(19) United States
(12) Patent Application Publication
(10) Pub. No.: US 2019/0302854 A1
(43) Pub. Date: Oct. 3, 2019

(54) ASSEMBLY STRUCTURE FOR OPEN-TYPE TABLET COMPUTER

(71) Applicant: ADLINK TECHNOLOGY INC., New Taipei City (TW)

(72) Inventors: Sheng-Feng WU, New Taipei City (TW); Yung-Jui CHAO, New Taipei City (TW)

(21) Appl. No.: 16/035,944

(22) Filed: Jul. 16, 2018

(30) Foreign Application Priority Data
Apr. 3, 2018 (TW) 107204456

(51) Int. Cl. G06F 1/16; H05K 7/14

(52) U.S. Cl. CPC G06F 1/1679; G06F 1/1643; H05K 7/1407; G06F 1/1658

(57) ABSTRACT

An assembly structure for an open-type tablet computer is disclosed. The open-type tablet computer comprises a computer main body which comprises base, a host system device, and a screen module exposed out of a front opening of the base. The assembly structure comprises locking members formed on a connection part around the base. When the computer main body is mounted on a fastening structure, the base can be embedded into a mounting hole of a body from the front of the fastening structure, and the connection part is stopped by the surface of a fastening part. The locking members can be inserted into a through hole of the body, respectively, and multiple jointing members can be locked, from a rear of the fastening structure, with the locking members, respectively. Therefore, the computer main body can be quickly aligned and assembled on with the fastening structure without extra mounting accessory.

This application claims the priority benefit of Taiwan patent application number 107204456, filed on Apr. 3, 2018.

### BACKGROUND OF THE INVENTION

### 1. Field of the Invention

The present invention relates to an assembly structure for an open-type tablet computer. More particularly, in the assembly structure of the present invention, a computer main body includes a plurality of locking members formed around a connection part of a base, and when the computer main body is mounted on a fastening structure, the locking members can be inserted through holes of a body of the fastening structure, respectively, and jointing members can be locked on the locking members, so that the computer main body can be quickly aligned and assembled on with the fastening structure more simply and conveniently.

### 2. Description of the Related Art

In recent years, with trends in Internet cloud technology and the Internet of Things, electronic devices such as computers, industrial computers, embedded computers, mobile tablet PCs, and touch-controlled computers are continuously being introduced into the market, and their developments are towards high computing functions, high computing speed, and smaller size. Particularly, the mobile tablet and touch-controlled computer have advantages of high efficiency, no fan, low power consumption and ultra-thin mechanism design, and can be also designed with an open frame structure to be efficiently installed and integrated in any space or chassis; furthermore, shells of the mobile tablet and touch-controlled computer can also be replaced by customized shells, so as to shorten product development and end product time-to-market. Therefore, the mobile tablet and touch-controlled computer are most suitable for multimedia guidance machines, automatic teller machines, entertainment machines, vending machines, self-checkout machines, electronic billboard, home automation machines, and conference displayers, and more smart life applications.

Furthermore, as electronic devices (such as mobile tablet PCs and touch-controlled computers) are widely used in daily life, the number of such installed computers and requirements for such computers are greatly increased, so the manufacturer must think about how to make the operations of assembling and disassembling, replacing components in the chassis or limited space more easily and more conveniently, under the limitation of the uniform size of the chassis. Furthermore. The overall assembly structures for such electronic devices must also be considered to meet costs and requirements in the tens of thousands of the installed electronic devices. Please refer to FIGS. 7 and 8. Abase A1 of a computer main body A includes a host system device A2, and a touch screen A3 exposed out of the front of the base A1, and a side board A11 formed outwardly on a periphery of the base A1. A buckle plate A41 of a plurality mounting accessories A4 are spaced apart from the back of the side board A11 of the base A1 by a distance, and a first screws A42 are inserted through the through holes A411 of the buckle plate A41, and second screws A43 are screwed into thread holes A412, and the first screws A42 are locked into the locking holes A12 of the base A1, respectively. When the computer main body A is mounted in a mounting hole B1 of a wall plate B, the side board A11 of the base A1 can be abutted with the peripheral surface of the mounting hole B1 through a washer A13. After the base A1 is inserted through the mounting hole B1, the buckle plates A41 of the mounting accessories A4 can be rotated outwardly to align with the back surface of the wall plate B, and the second screws A43 can be screwed into the thread holes A412 to push the wall plate B, so that the side board A11 of the base A1 can be tightly packed with the wall plate B by the second screws A43 of the mounting accessories A4, thereby combining the side board A11 and the wall plate B integrally.

However, the convention manner of mounting the computer main body A with the wall plate B requires many mounting accessories A4 which each also has a lot of components, so the material cost is high; furthermore, when the mounting accessory A4 is assembled with the base A1, the first screws A42 of the buckle plate A41 are locked into the locking hole A12, and after the computer main body A is mounted on the wall plate B, the second screws A43 of the buckle plate A41 are locked by screwing manner. Therefore, operations of the plurality of mounting accessories A4 need to use a large quantity of screws, so the conventional assembly process becomes more complicate and time-consuming, and the cost is high; furthermore, the user is not easy to perform the locking actions in a limited space. As a result, it is difficult to improve the conventional manner to assemble, disassemble and replace the components more simply and convenient.

Please refer to FIGS. 9 and 10. The base A1 of computer main body A is provided with a plurality of buckle holes A14 cut through a periphery thereof, and each mounting accessory A4 comprises a fastener A44, a screw A45 and a pushing plate A46, and the fastener A44 includes engaging hooks A441 bent and extended from two opposite sides thereof in the same direction, and the screw A45 is screwed through a thread hole A442 of the fastener A44 and a end portion A451 of the screw A45 is inserted into the fastener A44 and through a pivot hole A461 of the pushing plate A46, and a clasping sheet A452 on the end portion A451 can be stopped on a peripheral surface of the pivot hole A461. In order to mount the computer main body A in the mounting hole B1 of the wall plate B, the side board A11 of the base A1 is abutted with the peripheral surface of the mounting hole B1 first, and the engaging hooks A441 of the fasteners A44 can be clasped inside the buckle holes A14 of the base A1, respectively, and the screws A45 are screwed into the thread holes A442 to drive the pushing plate A46 to push the wall plate B along the fastener A44, so that the side board A11 of the base A1 can be tightly packed on the wall plate B by the pushing plates A46 of the mounting accessories A4, thereby integrally combining the base A1 and the wall plate B.

Compared with conventional structure, the mounting accessory A4 can reduce the use of one screw, but the fastener A44, the screw A45 and the pushing plate A46 also have complex structures and higher material costs, and, in the process of mounting the computer main body A on the wall plate B, the mounting accessory A4 also causes time-consuming problem and high-cost problem. Furthermore, after the fastener A44 is inserted into the mounting hole B1 of the wall plate B in the base A1, the engaging hook A441 is clasped in the buckle hole A14, so the mounting accessory A4 may fall off and lost during the process of mounting the mounting accessory A4 on the base A1 or disassembling the mounting accessory A4 from the base A1, and it is very inconvenient for user in operating the assembly process.

Therefore, what is needed is to develop an assembly structure to achieve the purpose that the computer main body A can be quickly assembled on the wall plate B without extra mounting accessory A4, to greatly reduce the material cost of the mounting accessory A4, and also to develop the assembly structure to solve the problem that the time-consuming problem and high-cost problem caused by the process of assembling or disassembling the mounting accessory A4.

### SUMMARY OF THE INVENTION

In order to solve the conventional problems, and the inventor develops the assembly structure for an open-type tablet computer according to the collected data, multiple tests and modifications, and years of research experience.

According to an embodiment of the present invention, a computer main body comprises a base, a host system device disposed on the base, and a screen module exposed out of a front opening of an accommodation space inside the base, and the base includes a connection part on a periphery thereof and a plurality of locking members disposed on the connection part, and when the computer main body is mounted on the fastening structure, the base and the host system device can be embedded into a mounting hole of the body from the front of the fastening structure, and the connection part is stopped by the surface of the fastening part, and each locking member is inserted through the through hole of the body corresponding thereto, and the jointing members are locked, from a rear of the fastening structure, with the locking members, respectively. Therefore, a large quantity of computer main bodies can be quickly aligned and assembled on the fastening structures, respectively, to integrally combine each other without extra mounting accessory, so that the material cost of the mounting accessory can be reduced greatly and overall assembly process can be simplified, thereby solving the time-consuming problem and high-cost problem caused by other accessory, and facilitating the user to perform the assembly process more simply and conveniently. As a result, the effect of simple structure, simple assembly process and lower cost can be achieved.

According to an embodiment, a ring-shaped gasket can be disposed between the connection part of the base of the computer main body and the fastening part of the body of the fastening structure, and the ring-shaped gasket can be embedded into a constraining ring groove recessed on the fastening part; and, when the computer main body is assembled on the fastening structure, the connection part can be tightly packed with the ring-shaped gasket to form a closed status, to prevent external vapor, powder or dust from entering the inside through a gap formed between the base and the body, thereby increasing dust-proof effect of water repellent effect of whole structure, and also achieving the requirement in IP65 level of water-proof and dust-proof verification.

### BRIEF DESCRIPTION OF THE DRAWINGS

The structure, operating principle and effects of the present invention will be described in detail by way of various embodiments which are illustrated in the accompanying drawings.

FIG. 1 is an elevational view of an assembly structure, according to an embodiment of the present invention.

FIG. 2 is an elevational view of the computer main body, according to an embodiment of the present invention.

FIG. 3 is an exploded view of the assembly structure of an embodiment of the present invention, before the computer main body is embedded into the fastening structure.

FIG. 4 is a top sectional view of a part of the assembly structure of an embodiment of the present invention, after the computer main body is being embedded into the fastening structure.

FIG. 5 is a top sectional view of a part of the assembly structure of an embodiment of the present invention, after the computer main body and the fastening structure are assembled.

FIG. 6 is a top sectional view of a part of an assembly structure of another embodiment of the present invention.

FIG. 7 is an elevational view of a back surface of a conventional tablet computer.

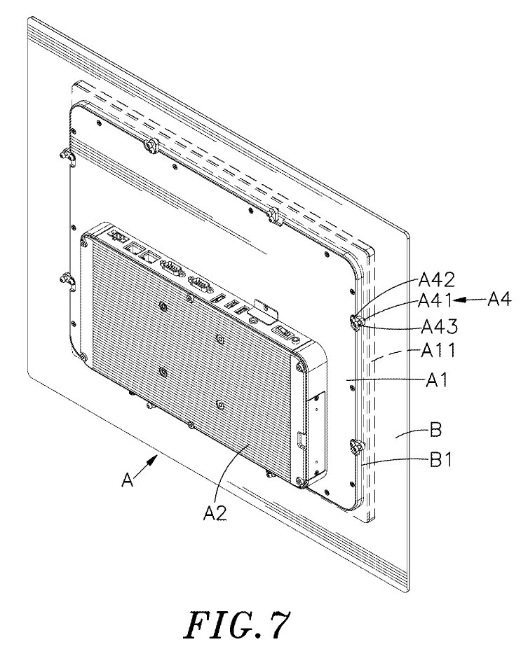

FIG. 8 is a top sectional view of a part of the conventional tablet computer embedded in the wall plate.

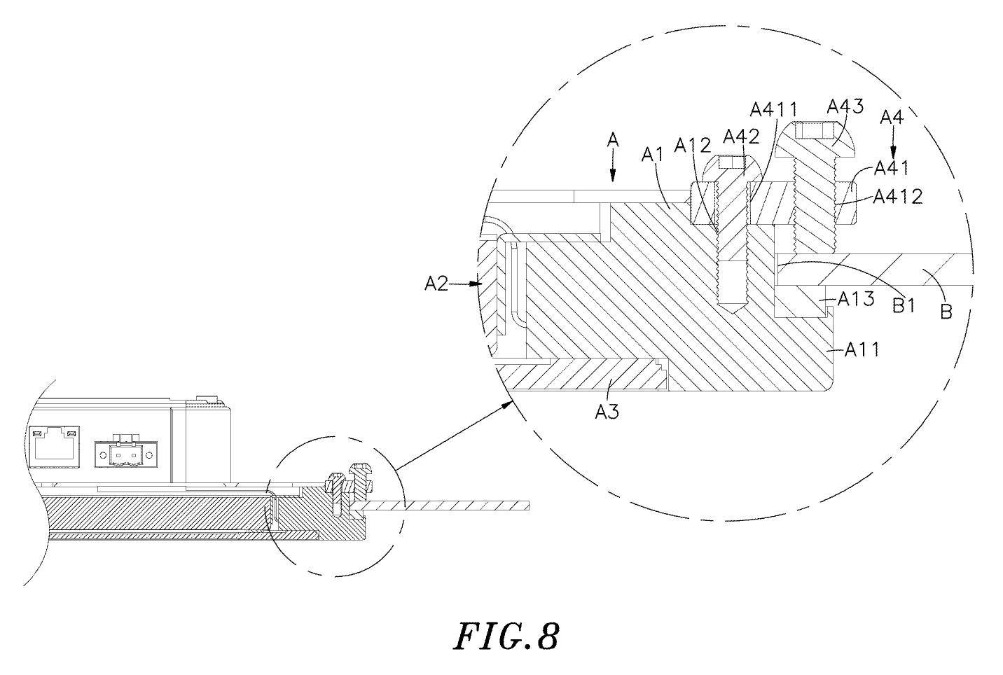

FIG. 9 is an elevational view of a back surface of another conventional tablet computer.

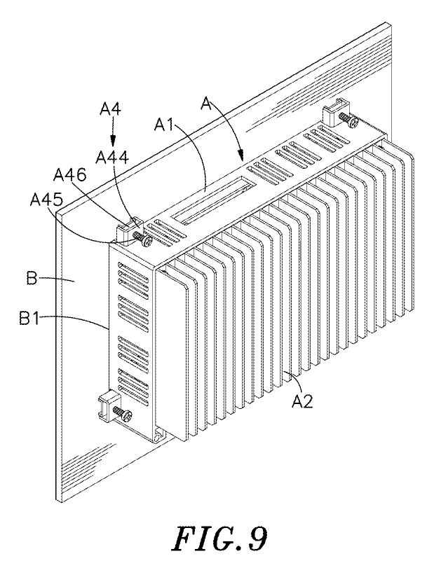

FIG. 10 is a top sectional view of a part of the conventional tablet computer embedded on the wall plate.

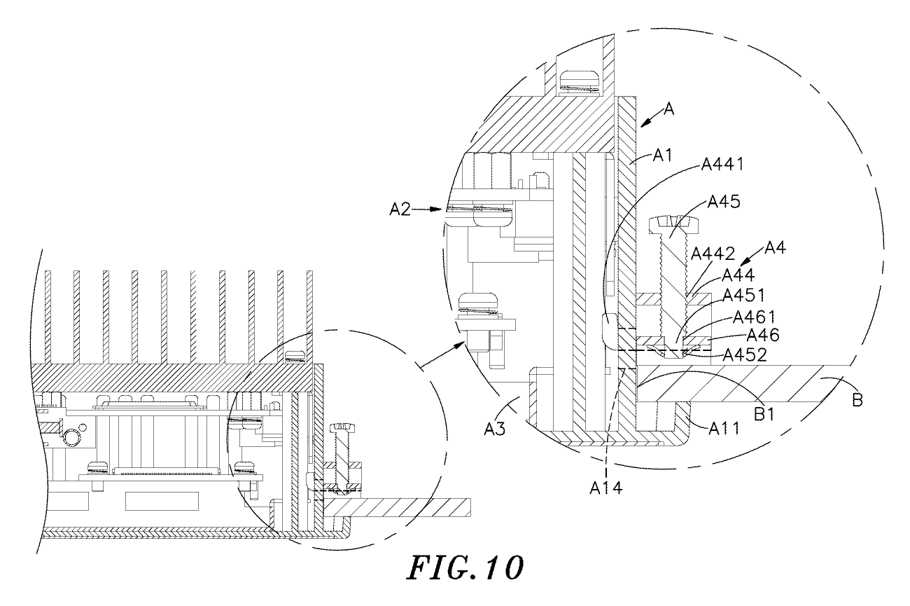

### DETAILED DESCRIPTION OF THE PREFERRED EMBODIMENTS

The following embodiments of the present invention are herein described in detail with reference to the accompanying drawings. These drawings show specific examples of the embodiments of the present invention. It is to be understood that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be understood that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise” and variations such as “comprises” or “comprising”, will be understood to imply the inclusion of stated elements but not the exclusion of any other elements.

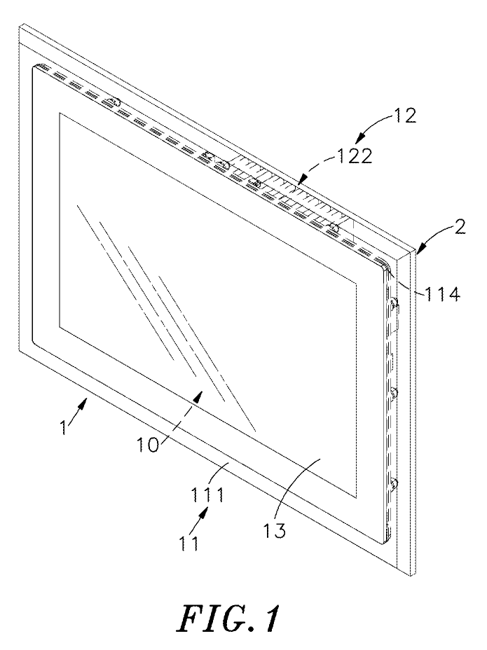

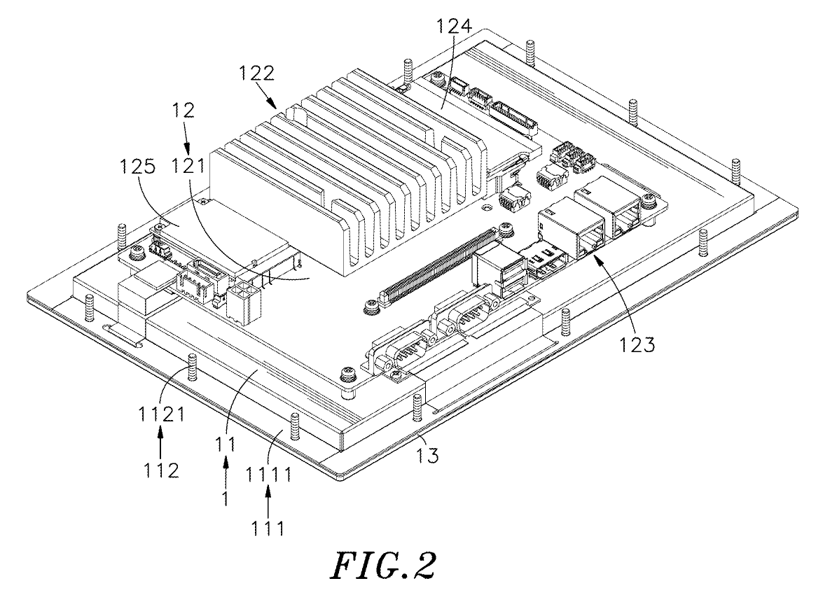

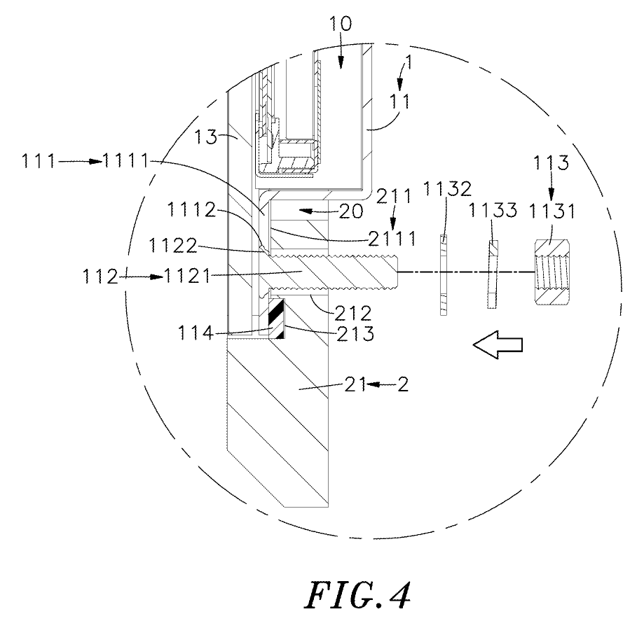

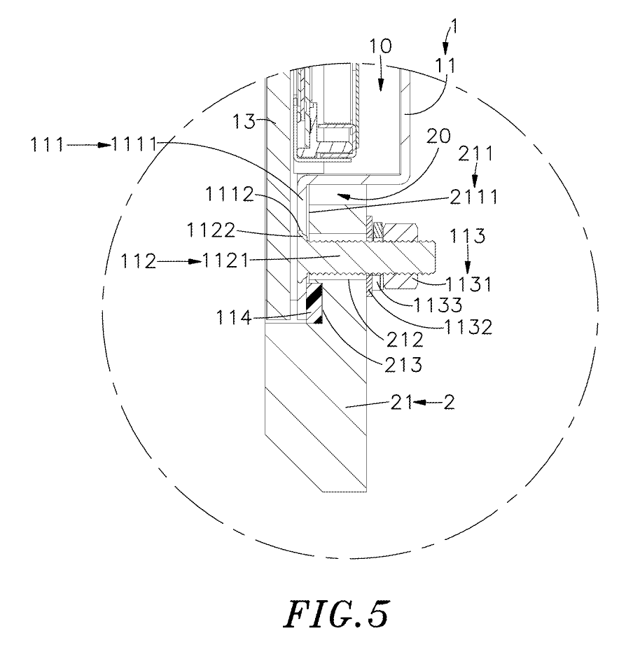

Please refer to FIGS. 1 to 5, which are elevational view of the assembly structure of an embodiment of the present invention, elevational view of a computer main body, exploded view of the assembly structure before the computer main body is embedded into the fastening structure, top sectional view of a part of the computer main body being embedded into the fastening structure, and top sectional view of a part of the assembly structure after the computer main body is assembled with the fastening structure, respectively. As shown in figures, the assembly structure of the present invention can be applied to assemble with a fastening structure 2, and the open-type tablet computer comprises a computer main body 1.

The computer main body 1 comprises a base 11 which can be a roughly-rectangular shell member, a host system device 12 and a screen module 13. The host system device 12 disposed on the base 11 includes a motherboard 121, a processing unit 122, (such as a central processor, a chipset, or a heat sink or a heat pipe on the central processor or the chipset), an input/output interface 123 (such as, a video port, a serial port, or a network port), a memory module 124 and a storage unit 125 (such as a hard disk). The screen module 13 (such as a display panel or a touch screen) is disposed in an accommodation space 10 recessed in a front portion of the base 11, and the screen module 13 is exposed out of the front opening of the accommodation space 10. The screen module 13 can be electrically connected to the motherboard 121 through a cable or a connector, to form the open-type tablet computer.

Furthermore, a connection part 111 is formed around the accommodation space 10 of base 11 and includes a flat peripheral wall 1111 outwardly bent from the periphery of the opening of the accommodation space 10. After the screen module 13 is mounted in the accommodation space 10 of the base 11, the peripheral portion of the screen module 13 can be abutted against the front side surface of the peripheral wall 1111 of the connection part 111 for positioning. A plurality of locking members 112 are perpendicularly protruded on a rear side surface of the peripheral wall 1111, and each locking member 112 is locked with a jointing member 113 corresponding thereto.

In this embodiment, the connection part 111 disposed around the base 11 is provided with a plurality of fixing holes 1112 cut through the peripheral wall 1111, and each locking member 112 comprises an extrusion-rivet screw 1121 with an outer thread, and each extrusion-rivet screw 1121 includes a hexagonal or circular head part 1122 formed on a side thereof and having a larger outer diameter. The head part 1122 of each locking member 112 can be pressed and riveted in the fixing hole 1112 of the peripheral wall 1111 corresponding thereto, to integrally combine each other, and the extrusion-rivet screw 1121 and the peripheral wall 1111 can be arranged at right angle. Each jointing member 113 comprises a nut 1131 configured to lock with the extrusion-rivet screw 1121 corresponding thereto, however, in actual application, the jointing member 113 can include a washer 1132 and a spring washer 1133 mounted on the extrusion-rivet screw 1121 between the head part 1122 and the nut 1131, so as to strengthen the friction of the nut 1131 abutted with the spring washer 1133 and the washer 1132 tightly, thereby preventing the nut 1131 from escaping easily.

in this embodiment, the fastening structure 2 is a chassis, and comprises a body 21, and the body 21 can be a hollow frame; however, in actual application, the structural design of the body 21 can be changed upon different purpose, for example, the body 21 can be a panel of a retaining frame, a wall plate or other wall. The body 21 can include a mounting hole 20, and a fastening part 211 formed on a periphery of the mounting hole 20. Preferably, the fastening part 211 can be a flat groove or a groove with continuous step differences. The fastening part 211 can include a supporting surface 2111 formed thereon thereof, and a plurality of through hole 212 cut through the supporting surface 2111.

In order to assemble host system device 12 and the fastening structure 2, the base 11 and the host system device 12 of the computer main body 1 are embedded into the mounting hole 20 of the body 21 from the front of the fastening structure 2, and the locking members 112 are inserted into and disposed in the through holes 212, respectively, and the guiding and constraining effect of the extrusion-rivet screws 1121 can facilitate the user to align for assembly. After the peripheral wall 1111 of the connection part 111 is stopped by the supporting surface 2111 of the fastening part 211, the washers 1132 and spring washers 1133 of the jointing members 113 can be mounted, from the rear of the body 21, on the parts of the extrusion-rivet screws 1121 exposed out of the through holes 212, respectively, in a sequential order. After the nut 1131 is locked on the extrusion-rivet screw 1121 corresponding thereto, the interval formed between the nut 1131 and connection part 111 can be reduced, so that the connection part 111 can be tightly packed on the fastening part 211 to integrally combine the with each other. By using the locking members 112 of the base 11 for assembly, the locking members 112 can be inserted through the through hole 212, respectively, from the front of the body 21, and the locking members 112 is then locked and fixed with the jointing members 113 from the back of the body 21, so that the computer main body 1 can be quickly aligned and assembled on with the fastening structure 2 without extra mounting accessory, and the material cost of the mounting accessory can be reduced greatly, and overall assembly process can be simplified, and a significant amount of computer main bodies 1 can be quickly assembled or disassembled, thereby solving the problem that the conventional process of mounting or dismounting other accessories consumes working hour and cost. As a result, it is simpler and convenient for the user in assembly operation, and the effect of simple structure, simple assembly process and lower cost can be achieved.

Furthermore, in an embodiment, a ring-shaped gasket 114 can be disposed between the connection part 111 of the base 11 and the fastening part 211 of the body 21, and the fastening part 211 comprises a constraining ring groove 213 recessed on the supporting surface 2111 and adjacent to outer periphery of the through holes 212, and the ring-shaped gasket 114 can be embedded in the constraining ring groove 213. When the computer main body 1 is assembled on the fastening structure 2, the peripheral wall 1111 of the connection part 111 can be tightly packed with the ring-shaped gasket 114 to form a closed status, to prevent external vapor, powder or dust from entering the inside through a gap formed between the base 11 and the body 21, thereby increasing dust-proof effect of water repellent effect of whole structure, and achieving the requirement in IP65 level of water-proof and dust-proof verification.

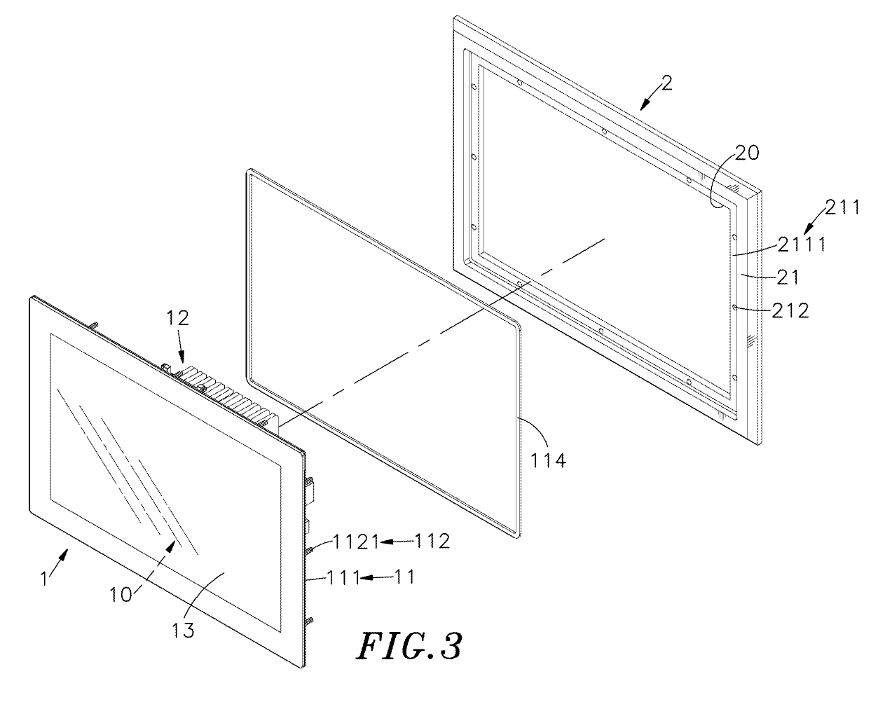

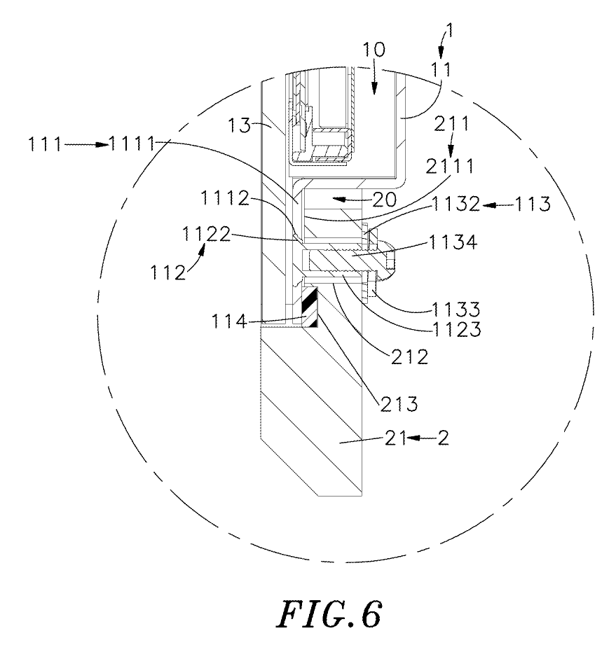

Please refer to FIGS. 3, 5 and 6, which are exploded view of the assembly structure before the computer main body is embedded into the fastening structure, top sectional view of a part of assembly structure after the computer main body is assembled with the fastening structure, and top sectional view of a part of assembly structure of other preferred embodiment, respectively. As shown in figures, the computer main body 1 of the fastening structure 2 of this embodiment are substantial the same as that of aforementioned embodiment, but the structures of the locking member 112 and the jointing member 113 of the base 11 of this embodiment are different from that of aforementioned embodiment. In this embodiment, the locking member 112 can be an extrusion-rivet bolt 1123 having an inner thread, and the head part 1122 can be pressed and riveted into the fixing hole 1112 of the peripheral wall 1111, so as to integrally combine each other, or, a bolt can be directly formed on the peripheral wall 1111 by extruding, burring or tapping manner, and the jointing member 113, which is in cooperation with the extrusion-rivet bolt 1123, can also include a screw 1134. When the base 11 of the computer main body 1 is assembled on the fastening structure 2, the extrusion-rivet bolts 1123 of the locking members 112 can be inserted into the through holes 212 of the body 21, respectively; furthermore, the washer 1132 and the spring washer 1133 can be mounted on the extrusion-rivet bolt 1123, and the screws 1134 of the jointing members 113 can be locked into the extrusion-rivet bolts 1123, respectively, so as to integrally combine each other. However, numerous modifications, variations and enhancements can be made thereto by those skilled in the art without departing from the spirit and scope of the disclosure set forth in the claims.

According to embodiments of the present invention, the computer main body 1 includes the host system device 12 disposed on the base 11, and the screen module 13 exposed out of the front of the base 11; and, the base 11 includes the connection part 111 on the periphery thereof and the plurality of locking members 112 disposed on the connection part 111; and, when the computer main body 1 is mounted on the fastening structure 2, the base 11 can be embedded into the mounting hole 20 of the body 21, and the connection part 111 is stopped on the surface of the fastening part 211 on the periphery of the mounting hole 20, and after the locking members 112 are inserted into the through hole 212 on the body 21, respectively, the jointing members 113 can be locked with the locking members 112, respectively, so that the computer main body 1 can be quickly aligned and assembled with the fastening structure 2 to integrally combine each other, thereby facilitating the user to operate the assembly process more simply and conveniently, and achieving the effect of simple structure, simple assembly process and lower cost.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. An assembly structure for an open-type tablet computer, applied to assemble with a fastening structure, wherein:
the fastening structure comprises a body with a mounting hole, and a fastening part comprising a plurality of through holes formed around the mounting hole; and
wherein the open-type tablet computer comprises a computer main body, and the computer main body comprises a base comprising an accommodation space inside, a host system device disposed on the base, and a screen module exposed out of a front opening of the accommodation space, and the base and the host system device are embedded into the mounting hole of the body from the front of the fastening structure;
wherein the assembly structure comprises a connection part disposed around the base and formed outwardly to block a surface of the fastening part, and the connection part comprises a plurality of locking members and a plurality of jointing members, and the plurality of locking members are inserted through the plurality of through holes, respectively, and the plurality of locking members are locked, from a rear of the fastening structure, with the plurality of jointing members, respectively, so as to tightly pack the connection part and the fastening part integrally.

2. The assembly structure according to claim 1, wherein the host system device of the computer main body comprises a motherboard, a processing unit, an input/output interface, a memory module and a storage unit, and the screen module is electrically connected to the motherboard, so as to form the open-type tablet computer.

3. The assembly structure according to claim 1, wherein the connection part of the base of the computer main body comprises a flat peripheral wall, and the flat peripheral wall is provided with a plurality of fixing holes cut therethrough and a plurality of locking members formed on a rear side surface thereof, and each of the plurality of locking members comprises an extrusion-rivet screw with an outer thread, and each of the plurality of extrusion-rivet screws comprises a head part formed on a side thereof and configured to rivet into one of the plurality of fixing holes corresponding thereto, and each of the plurality of jointing members comprises a nut configured to lock with one of the plurality of extrusion-rivet screws corresponding thereto.

4. The assembly structure according to claim 3, wherein each of the plurality of jointing members comprise a washer and a spring washer, and the washer and the spring washer are mounted on the extrusion-rivet screw of one of the plurality of locking members corresponding thereto.

5. The assembly structure according to claim 1, wherein the connection part of the base of the computer main body comprises a flat peripheral wall, and the flat peripheral wall is provided with a plurality of fixing holes cut therethrough and a plurality of locking members formed on a rear side surface thereof, and each of the plurality of locking members comprises an extrusion-rivet bolt with an inner thread, and each of the plurality of extrusion-rivet bolts comprises the head part formed on a side thereof and configured to rivet into one of the plurality of fixing holes corresponding thereto, and each of the plurality of jointing members comprises a screw configured to lock with one of the plurality of the extrusion-rivet bolts corresponding thereto.

6. The assembly structure according to claim 5, wherein each of plurality of the jointing members comprises the washer and the spring washer, and the washer and the spring washer are mounted on the extrusion-rivet bolt of one of the plurality of locking members corresponding thereto.

7. The assembly structure according to claim 1, further comprising a ring-shaped gasket disposed between the connection part of the base of the computer main body and the fastening part of the body of the fastening structure.

8. The assembly structure according to claim 7, wherein the fastening part of the body comprises a constraining ring groove recessed adjacent to outer periphery of the plurality of through holes, and the ring-shaped gasket is embedded in the constraining ring groove, and the connection part of the base is tightly packed on the ring-shaped gasket to form a closed status.
